(19) United States
(12) Patent Application Publication
(10) Pub. No.: US 2012/0325282 A1
(43) Pub. Date: Dec. 27, 2012

(54) SOLAR CELLS WITH GRID WIRE INTERCONNECTIONS

(75) Inventors: Richard Snow, Redwood City, CA (US); Eric Lee, San Jose, CA (US); Burak Metin, San Jose, CA (US); Serkan Erdemli, San Jose, CA (US); Anjuli Appapillai, San Jose, CA (US)

(73) Assignee: SoloPower, Inc., San Jose, CA (US)

(21) Appl. No.: 13/168,023

(22) Filed: Jun. 24, 2011

(51) Int. Cl. H01L 31/05; H01L 31/18

(52) U.S. Cl. 136/244; 438/67; 257/E31.11

(57) ABSTRACT

A plurality of solar cells is connected together in a shingled fashion. Each of the solar cells includes grid wires that are attached to an electrode of the solar cell so as to receive charge carriers produced when photons are absorbed by the solar cell. The grid wires are then interconnected with adjacent solar cells when the solar cells are shingled together. The grid wires may be applied to the solar cells via a laminate and the electrical interconnection of the grid wires may be achieved by the use of a conductive epoxy.

### BACKGROUND OF THE INVENTION

1. Field of the Invention

The present invention relates to solar cells and, in particular, concerns CIGS based solar cells that are interconnected with each other using grid wire structures.

2. Description of the Related Art

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film, an ITO film or a CdS/ZnO/ITO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Typically, there is also a busbar or pattern of conductive gridding that is formed on the upper surface of the absorber which gathers the charge carriers generated by the absorber. This busbar or conductive gridding is deposited or formed using well-known techniques and can represent a significant portion of the total cost of the solar cell. For example, silver ink is often used for screen printing the gridding and this can represent a significant portion of the overall cost of a solar module. Also, the gridding material directly shadows the solar cell below so smaller dimensioned wires translates directly into greater photocurrent. Further, if the busbar or conductive gridding is deposited or patterned poorly on the solar cell, the entire solar cell may not function as desired and will have to be removed. Hence, there is a need in solar cells, such as CIGS solar cells, for better ways of forming electrical conductors on the solar cells to collect the charge carriers formed by photons being absorbed by the absorber.

Further, in standard CIGS as well as amorphous Si module technologies, the solar cells can be manufactured on flexible conductive substrates such as stainless steel foil substrates. Due to its flexibility, a stainless steel substrate allows low cost roll-to-roll solar cell manufacturing techniques. In such solar cells built on conductive substrates, the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells contained in the packaging against mechanical damage. Each module typically includes multiple solar cells which are electrically connected to one another using the above mentioned stringing or shingling interconnection methods.

In standard silicon, CIGS and amorphous silicon cells that are fabricated on conductive substrates such as aluminum or stainless steel foils, the solar cells are not deposited or formed on the protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another.

Efficient packing of cells within the module is an important contributor to the power of the module, and limiting the area of the module without cell coverage is desirable. Shingling the cells to construct the string allows for a higher power module. For example, if the cell length is 30-40 mm (a common cell length for shingle cells) and there is a 2 mm gap between cells, the module power would be 5% less than if the cells were shingled, with no space between the cells.

Conversely, shingling cells take up extra cell material because there will be some area where the cells overlap. The cell is often the largest cost contributor within a module. If the bottom cell has to pass current to the top cell through this overlap area several mm are generally required for a low resistance contact of conductive adhesive.

And so it is desirable to shingle cells with the smallest possible overlap.

Shingling and stringing in this manner can, however, be complex and expensive as specialized components may have to be formed on the solar cells to facilitate such interconnection. More specifically, interconnecting portions of the busbar and conductive gridding on one solar cell to the substrate on another solar cell can be complex and require additional processing steps. Hence, there is a need to simplify the connection between solar cells in shingling or stringing applications.

### SUMMARY OF THE INVENTION

The aforementioned needs are satisfied by at least one embodiment of the present invention which comprises an assembly of solar cells that includes a first solar cell having a first electrode and a second electrode and defining a first and a second side and a first and a second edge. In this embodiment, the assembly also includes a second solar cell having a first electrode and a second electrode and defining a first and a second side and a first and a second edge wherein a portion of the second side of the second solar cell adjacent the first edge is positioned at an interface adjacent a portion of the first side of the first solar cell adjacent the second edge of the first solar cell. In this embodiment, the assembly also includes a first plurality of grid wires that are disposed on the first surface of the first solar cell and electrically connected to the first electrode of the first solar cell so as to collect charge carriers generated from the absorption of light by the first solar cell wherein the first plurality of grid wires are electrically connected to the second electrode of the second solar cell so as to electrically connect the first and second solar cells. The first and second cells can be shingled with the smallest possible overlap because the current is not passed from one cell to the next through the overlap area, it is passed through the contact wires. The only limitation on the overlap dimension is the accuracy of the equipment placing the cells.

Shingling with contact wires is also more mechanically robust towards handling than a traditional shingle because, in a traditional shingle the overlap area provides both the electrical and mechanical connection, whereas with a contact wire shingle the electrical connection is provided by the wires and the mechanical connection by the dielectric film. Also, the wires can extend the length of the cells and provide a larger area for electrical connection to lower the contact resistance while being robust towards local physical dislocations.

With the contact wire approach a dielectric film can cover the entire overlap area. The dielectric film protects a cell from scraping against another cell and causing shunting or mechanical wear.

The aforementioned needs are also satisfied by another embodiment of the present invention which comprises a method of interconnecting a plurality of solar cells each having a first and second surface and a first and second edge. In this embodiment, the method comprises: (i) positioning grid wires on a first surface of the plurality of solar cells so that the grid wires collect charge carriers produced by the solar cells in response to the solar cells absorbing photons; (ii) positioning a portion of the second surface of one solar cell adjacent the first edge of one solar cell adjacent the first surface of another solar cell adjacent the second edge of the other solar cell at an interface so that the plurality of grid wires of the other solar cell electrically contact the one solar cell; and (iii) repeating the positioning of act (ii) until a shingled array of electrically connected solar cells is formed.

These and other objects and advantages of the present invention will become more apparent from the following description take in conjunction with the accompanying drawings.

### BRIEF DESCRIPTION OF THE DRAWINGS

FIG. 1 is a schematic side view of a thin film solar cell including a Group IBIIIAVIA compound absorber layer;

FIG. 2 is a simplified isometric view of a thin film solar cell that has a plurality of grid wires extending therefrom;

FIG. 3A is a top view of a plurality of thin film solar cells of FIG. 2 that have been attached to each other by grid wires;

FIG. 3B is a bottom view of the plurality of thin film solar cells of FIG. 3A;

FIG. 3C is a top perspective view of another embodiment of a of a thin film solar cell similar to the solar cells of FIG. 2;

FIG. 3D is a side view of the thin film solar cell of FIG. 3C;

FIG. 3E is a side view of a plurality of thin film solar cells of FIGS. 3C and 3D as they are shingled together;

FIG. 4 is a top view of another implementation of a plurality of thin film solar cells of FIG. 2 that have been interconnected together by grid wires;

FIGS. 5A and 5B are side schematic views of a laminate that may be used to attach a plurality of grid wires to the thin film solar cells of FIG. 2;

FIG. 6 is a side schematic view of a portion of a thin film solar cell where the laminate of FIGS. 5A and 5B is attached to an electrode of the thin film solar cell;

FIGS. 7A and 7B are schematic top and bottom views of one embodiment of the laminate of FIGS. 5A and 5B illustrating through holes extending through the laminate to permit electrical connection to the grid wires for interconnection of different solar cells; and

FIGS. 8A-8C are progressive top and sectional views of one embodiment of the laminate of FIGS. 7A and 7B as it is used to interconnect two solar cells via a shingling process.

### DETAILED DESCRIPTION OF THE PREFERRED EMBODIMENT

Reference will now be made to the drawings wherein like numerals refer to like parts throughout. Referring to FIG. 2, a solar cell 20 with an upper surface 21 is shown. The upper surface 21 may comprise an anode or a cathode of the solar cell 20. As is also shown, a plurality of grid wires 22 is coupled to the surface 21 in such a way that charge carriers generated by the absorption of photons into the solar cell 20 will be collected and provided to the plurality of grid wires 22.

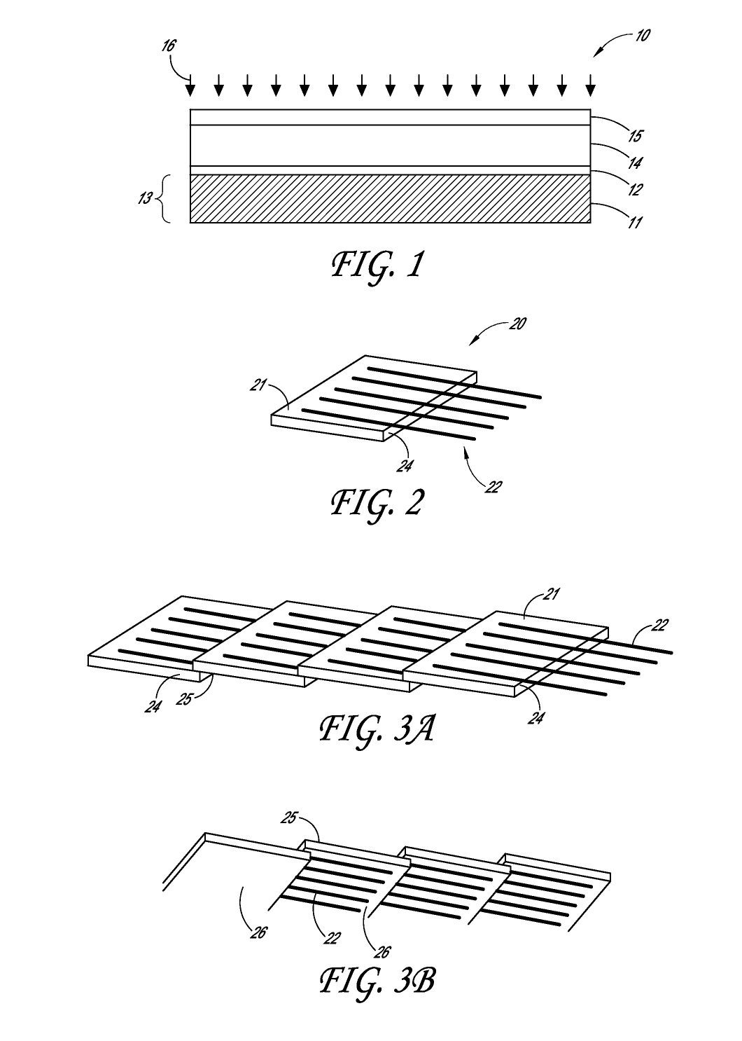

In one embodiment, the grid wires 22 comprise narrow wires that have a low electrical resistivity coating that allows for electrical connection to a transparent conductive layer 15 or transparent conductive oxide (TCO) (FIG. 1) on the solar cell 20. In this implementation, the transparent conductive oxide 15 receives the charge carriers generated by absorption of the photons and delivers these charge carriers to the grid wires 22. The grid wires 22 in one specific embodiment comprise wires that have a diameter of approximately 50 microns to 150 microns and have a metallic core such as a copper or silver core. The wires may also be flat strips with rectangular or square cross sections. In this implementation, the coating may comprise a carbon based coating that allows the grid wires 22 to adhere to the transparent conductive oxide 15 through the application of heat and/or pressure. In one specific example, the grid wires 22 are spaced every 3 to 6 mm on a particular solar cell 20 and the solar cell 20 is approximately 430 mm in width. It will be appreciated, however, that the exact size of the solar cell and grid wires 22 as well as the density of the grid wires 22 on the cell may vary depending upon the implementation without departing from the spirit and scope of the present invention. In another implementation, an array of the grid wires in a spaced apart and parallel arrangement may be held together by a transparent adhesive layer.

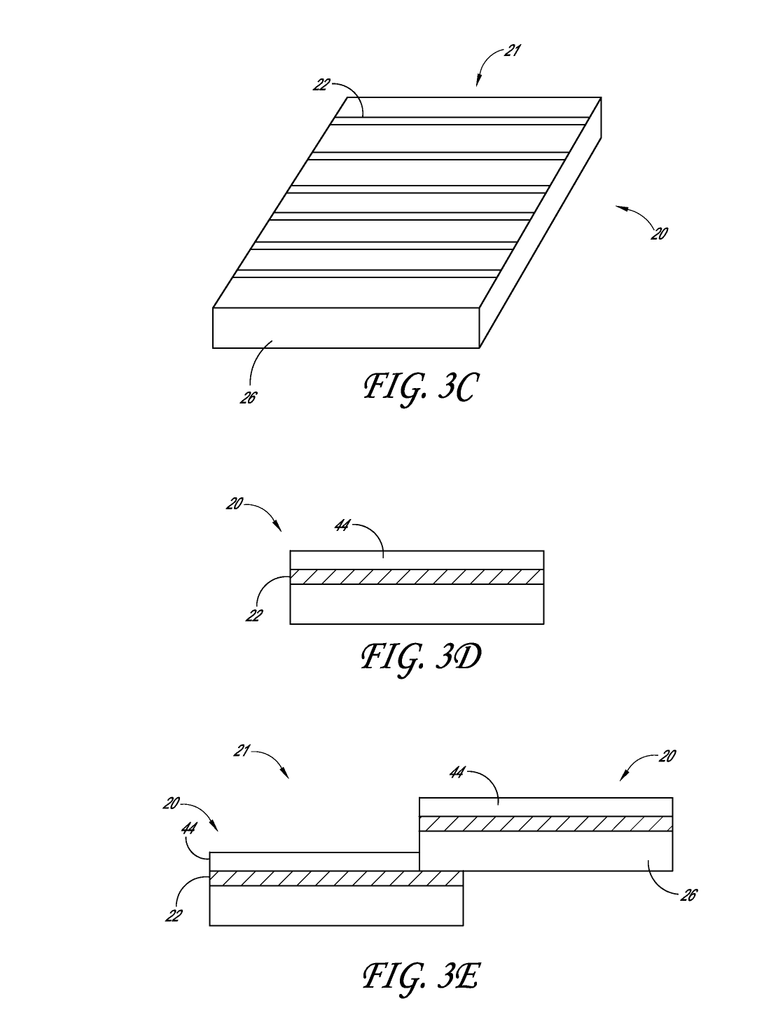

As shown in FIG. 2, the plurality of grid wires 22 are arranged so as to extend off of a first edge 24 of the solar cell 20 to permit subsequent interconnection to an adjacent solar cell 20 in a shingling manner. FIGS. 3A and 3B illustrate one embodiment of this process. The grid wires 22 from the upper surface 21 of one solar cell 20 are then connected to a bottom surface 26 of the next adjacent solar cell 20. In one embodiment, the bottom surface 26 comprises a conductive substrate made from a material such as stainless steel foil, or a stainless steel foil coated with other conductive materials such as ruthenium or molybdenum layers. The bottom surface 26 generally forms one electrode of the cell 20, e.g., the anode, with the upper surface 21 forming the other, e.g., the cathode.

As is also shown in FIGS. 3A and 3B, the first edge 24 of one solar cell 20 can overlap the second edge 25 of the adjacent solar cell 20. Alternatively, in some implementations the solar cells 20 can be positioned substantially coplanar to each other but separated by a small gap, e.g. 150 microns where the grid wires 22 then extend from the upper surface of one cell 20 down to the lower surface of the adjacent cell 20. Typically, there is a well-known physical interconnect that retains the solar cells in this shingled orientation or in the substantially co-planar orientation. It will also be appreciated that while FIGS. 3A and 3B illustrate the grid wires 22 extending substantially across the bottom surface 26 of the adjacent solar cell 20, the grid wires 22 need only to physically connect to a small portion of the bottom surface 26 to deliver the current from one solar cell 20 to the next.

As is shown in FIGS. 3C-3E, in some implementations, the grid wires 22 need not extend outward from the edge of a particular cell 20. As shown in FIG. 3C, the grid wires 22 can be positioned so as to remain entirely on the upper surface 21 of a cell 20. As is shown in FIG. 3D, the grid wires 22 are formed on the upper surface 21 of the cell 20 and are covered by uncured adhesive 44 which is described in greater detail below. As discussed below, the adhesive 44 may include a moisture barrier material and may also be formed as part of a carrier layer 40 that can also function as a moisture barrier. In the embodiment of FIGS. 3C-3E, the adhesive 44 can then be cured and the bottom surface 26 of an adjacent cell 20 or the second cell can be positioned proximate to the surface 21 of the first cell so as to be interconnected by shingling. As is shown in FIG. 3E, the second cell also includes the grid wires and the uncured adhesive 44 to shingle-interconnect it to a third solar cell (not shown). The curing process is also described in greater detail below. As shown in FIGS. 3C-3E, the adhesive layer is used for adhering the grid wires 22 on the upper surface 21, attaching/interconnecting the solar cells to one another in a shingled fashion, and forming a moisture barrier coating the grid wires and the upper surface. The grid wires 22 are highly conductive which means that the contact area between adjacent cells 20 can be reduced without reducing the amount of current flowing from one cell to the other. Thus, the amount of the cells 20 that are shaded by the adjacent cell when shingled is reduced which increases the output of the cells 20.

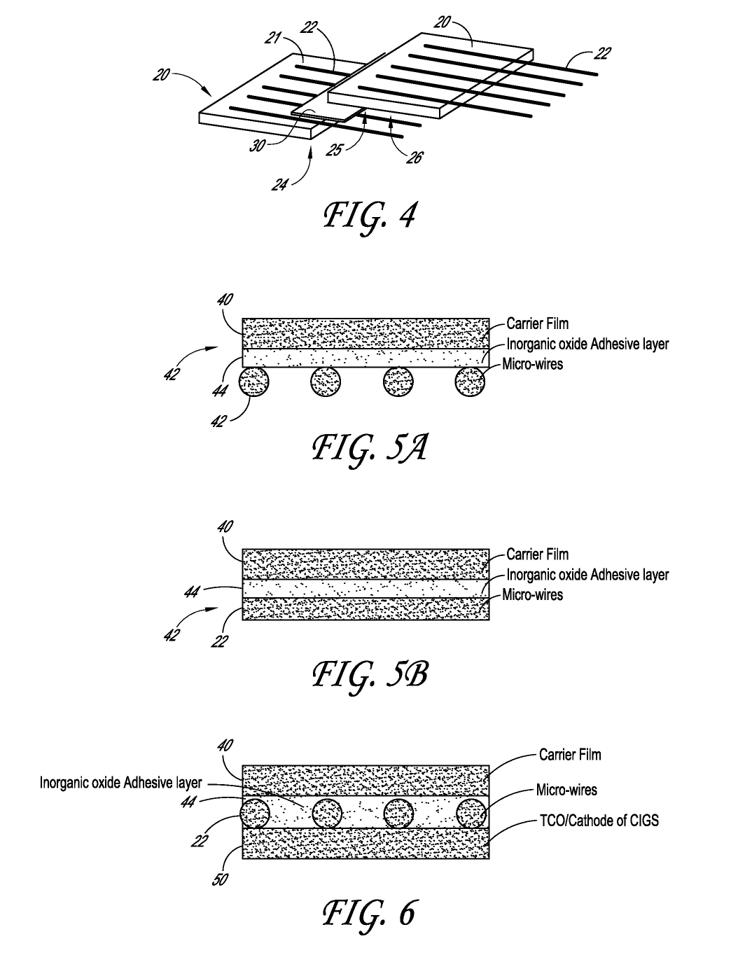

Referring to FIG. 4, as there is physical contact between the top surface 21 of one solar cell 20 with the bottom surface 26 of the adjacent solar cell 20, it may be desirable to include a dielectric 30 at the interface to provide additional insulation between the surfaces 21 and 26. In one implementation the dielectric comprises an EPE (EVA-PET-EVA laminate), or some derivative of EPE such as a (thermoplastic-PET-thermoplastic laminate) or PET only type dielectric material that is coupled to the edge of the bottom surface 26 that physically contacts the upper surface 21 of the adjacent solar cell 20. It will be understood that the dielectric 30 or some other insulator may be positioned so as to be above the grid wires 22, in between the grid wires 22 or some combination thereof.

In some implementations, it may be desirable to pre-form an array of grid wires 22 onto a carrier 40 for subsequent application to a surface of the solar cell. FIGS. 5A and 5B illustrate one such example of the array of grid wires 22 being formed onto the carrier 40. In this implementation, the grid wires 22 are attached to a laminate 42 that comprises the carrier 40 and an adhesive layer 44 or bonding layer. The carrier 40, in this implementation, may comprise materials such as fluorinated ethylene propylene (FEP), ethylene tetraflouroethylene (ETFE), polyethylene terephthalate (PET) or thermoplastic olefin. In some implementations, the carrier layer 40 is approximately 25 um to 350 um thick, but typically 50 or 75 um, but the exact thickness can, of course, vary depending upon the implementation without departing from the spirit of the present invention.

The plurality of grid wires 22 may be embedded into the adhesive 44 so as to be held by the laminate 42. In one implementation, the adhesive layer 44 may comprise a thermoplastic olefin layer that includes inorganic oxides such as silicon oxide SiO₂ or aluminum oxide AlO₂. The inorganic oxides which may also be transparent may be included as fine particles which are distributed in the adhesive matrix. Inorganic oxides can function as a moisture barrier that inhibits the penetration of moisture into the absorber layer 14 (FIG. 1) of the CIGS solar cell 20. It is understood that moisture can cause detrimental effects to a CIGS-based solar cell and the laminate 42 may be constructed so as to inhibit this moisture penetration either by the formation of the carrier film 40, the composition of the adhesive layer 44 or some combination thereof. In one implementation, the adhesive layer 44 has a thickness of approximately 50 micrometers; however, the exact composition of the adhesive layer can vary depending upon the application without departing from the scope of the present teachings. The inorganic oxides may be positioned as part of the adhesive or the inorganic oxides may be formed into a layer that is interposed between the carrier film 40 and the adhesive layer 44 or form a layer at some other region of the laminate 42. As will also be apparent from the following description, the carrier layer 40 may form a first moisture barrier layer and the adhesive layer 44 with the inorganic oxides may form a second moisture barrier layer depending upon the implementation.

FIG. 6 illustrates how the laminate 42 with the encapsulated grid wires 22 is adhered to a cathode 50 of the CIGS based solar cell 20. The laminate 42 of FIGS. 5A and 5B is placed on the cathode 50 with the adhesive layer 44 in an uncured state covering the surface of the cathode 50. By placing the grid wires in a pre-assembled laminate before applying to the cathode 50, wire misalignment and breakages may be prevented. The adhesive layer 44 is then cured by the application of pressure and heat such that the adhesive flows around the grid wires 22 and bonds them to the cathode 50. The cured adhesive layer also forms a moisture barrier layer or moisture seal layer on the on the cathode surface. This process also brings the grid wires 22 into physical contact with the cathode 50 to thereby electrically connect the cathode 50 to the grid wires 22 so that the grid wires 22 receive the charge carriers generated by the absorption of photons in the absorber 14. In one implementation, during the curing process, pressure may be applied onto the carrier layer to bring the grid wires 22 into physical contact with the cathode surface. The cured adhesive layer 44 is transparent and does not inhibit light transmission, and the curing process may also help to increase the density of the inorganic oxides by bringing them closer around the grid wires 22, thereby establishing a better moisture barrier on the grid wire surface portions that are not in physical contact with the cathode 50. In one specific implementation, the laminate 42 is heated to approximately between 200 C and 400 C in an environment of approximately 30 psi to 50 psi to adhere the adhesive layer 44 to the cathode 50 and to have the grid wires 22 contact and bond to the cathode. In another embodiment, after the laminate 42 is placed on the cathode 50 and before curing the adhesive layer 44 or partially curing it, the carrier 40 is peeled off the adhesive layer.

It will be appreciated that the carrier 40 may be made of a light transmissive material and can form a component of the completed solar cell assembly. Alternatively, the carrier 40 may be a temporary component that permits the application of the grid wires 22 to the upper surface of the substrate in the manner described above and the carrier 40 can then be removed from the solar cell 20 before the interconnection process.

It will be further appreciated that the grid wires 22 are formed onto the laminate 42 prior to application of the laminate 42 onto the CIGS solar cell 10. Thus, if the grid wires 22 are poorly arranged on a portion of the laminate 42, that portion of the laminate 42 can then be removed from the manufacturing process chain and not applied to the solar cell 10. This is in contrast to deposition of conductive busbars or grids directly onto the solar cell 10 where erroneous or poor application of the conventional busbar or grid onto the solar cell 10 usually requires the removal of the entire solar cell 10 from the manufacturing process chain.

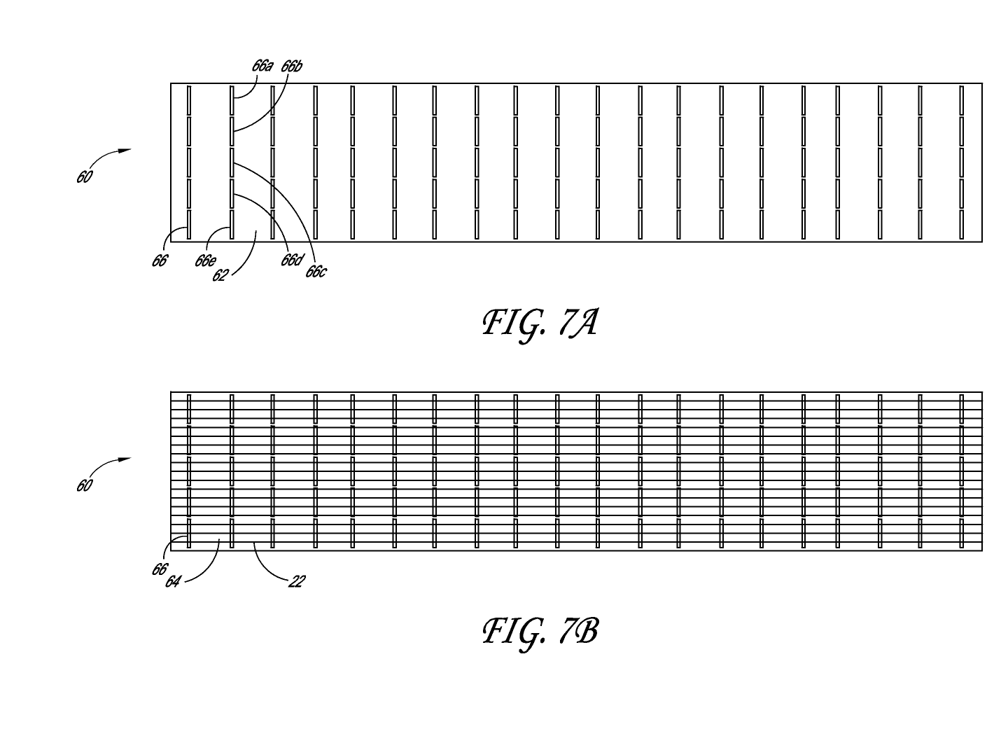

FIGS. 7A and 7B are top and bottom views of a laminate material 60, similar to the laminate 42 of FIGS. 5A, 5B and 6, that includes encapsulated grid wires 22. As shown, the laminate material 60 is formed into a sheet having a first side 62 and a second side 64 with a plurality of openings 66 extending from the first side 62 to the second side 64. As shown in FIG. 7B, a plurality of grid wires 22 may be adhered to the second side 64 of the sheet 60 in a manner similar to the manner discussed above.

As shown, the grid wires 22 are generally extending in a direction that is perpendicular to the direction of openings 66. The openings 66 are generally comprised of a plurality of openings 66a-66e arranged into a line. The openings 66a-66e are generally sized and located so that each of the grid wires 22 extends across one of the openings 66a-66e or can otherwise be electrically contacted there through.

The sheet 60 is formed as a laminate sheet suitable for cutting such that individual pieces of laminate 70, such as the laminate 42 described above in connection with FIGS. 5A, 5B and 6, can be cut from the sheet 60. In the exemplary embodiment shown in FIGS. 7A and 7B, there are a total of 19 different individual pieces of laminate that can be formed by cutting the sheet 60 where each individual piece will be able to couple between two different solar cells 20 in a shingling manner

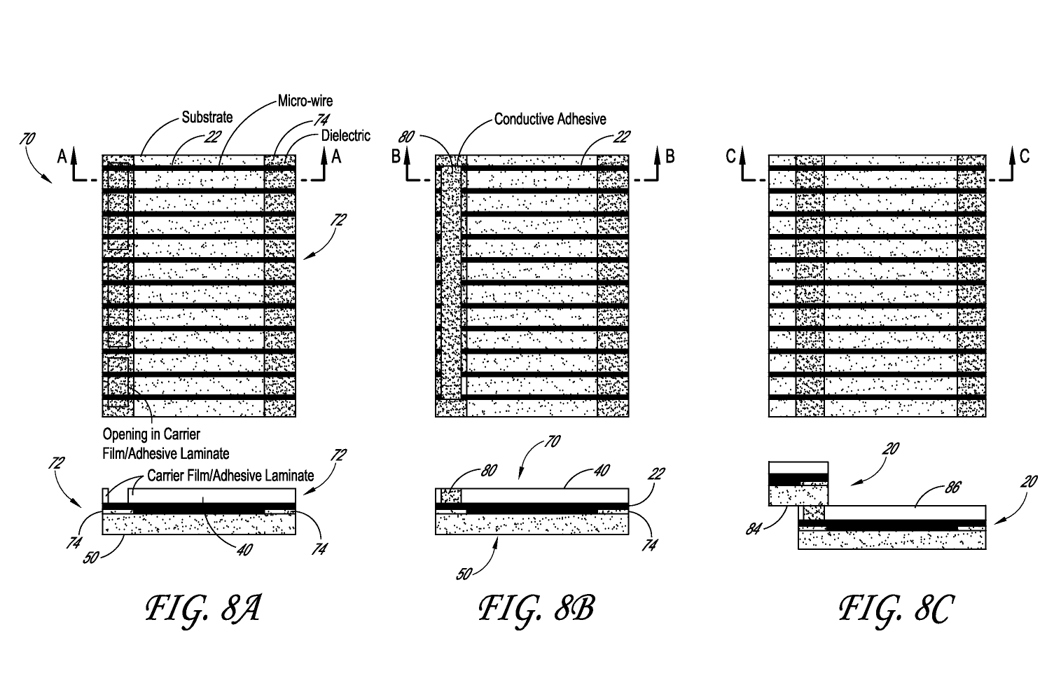

Referring now to FIGS. 8A-8C, the use of individual pieces of laminate 70 cut from the sheet 60 will now be described in forming a shingled arrangement of solar cells 20. FIGS. 8A-8C illustrate a top view with a superimposed side view of an individual laminate piece 70 as it is positioned on the solar cell 20. For clarity, the underlying grid wires 22 are shown through a transparent top view of the laminate piece 70. In this implementation, the laminate piece 70 comprises a laminate of a carrier 40 with an adhesive 44 attached thereto encapsulating the grid wires 22 in substantially the same manner as described above.

As is also shown, a dielectric layer 74 may be positioned at least one of the lateral edges 72 of each of the laminate pieces 70. As discussed above, the dielectric layer 74 provides additional insulation between the electrical components of one solar cell from another at the edges thereby inhibiting undesired electrical contact and potential shorting. In one implementation, strips of the dielectric layer 74 is interposed between the grid wire 22 and the main body of the solar cell 20. The dielectric layer 74 is, in one implementation, formed on the cathode 50 of the solar cell 20. In one implementation, the dielectric layers 74 comprise UV-curable or heat and pressure curable, transparent type dielectric, for example a dielectric resin, that may be between 2 to 15 um and up to 50 um thick and may be deposited by printing or dispensing techniques. The dielectric resin may be an acrylate, epoxy or other polymer.

As shown in FIG. 8B, once the laminate piece 70 is positioned on the solar cell 20, a conductive adhesive 80 is then positioned into the openings 66. Preferably, the conductive adhesive 80 is positioned initially into the openings 66 in a viscous state to thereby allow the conductive adhesive 80 to flow around the grid wires 22 and electrically interconnect with the grid wires 22. In one embodiment, the conductive adhesive 80 comprises a silver filled epoxy but other conductive epoxies or adhesives can be used without departing from the scope of the present invention.

As shown in FIG. 8C, a conductive bottom surface 84, or anode, of another solar cell 20 can then be positioned on an upper surface 86 of the laminate piece 70 so as to be in physical contact with the conductive adhesive 80 that is filling the opening 66 and positioned at or above the upper surface 86 of the laminate piece 70. Once the conductive adhesive 80 extending between the grid wires 22 and the conductive bottom surface 84 is cured, electrical contact is thereby made between the two shingled solar cells 20 through the conductive adhesive. In this manner, shingled interconnection of solar cells can be accomplished in a simpler, less expensive manner. Although FIGS. 8A-8C show two stripes of the dielectric layer 74 disposed adjacent the edges of each solar cell, there may be a single strip disposed only at the edge where the conductive adhesive 80 fills the opening 66.

From the foregoing it will be appreciated that the grid wires allow for more efficient collection of charge carriers produced by the solar cells. The grid wires have a reduced area which further reduces shading by the grid wires that could reduce the output of the solar cells in response to sunlight. Further, the grid wires allow for high conductivity connections between adjacent cells when the cells are shingled which further reduces shading and enhances the efficiency of the cells.

Although the foregoing description has shown, illustrated and described various embodiments of the present invention, it will be apparent that various substitutions, modifications and changes to the embodiments described may be made by those skilled in the art without departing from the spirit and scope of the present invention. Hence, the scope of the present invention should not be limited to the foregoing discussion but should be defined by the appended claims.

What is claimed is:

1. An assembly of solar cells comprising:
a first solar cell having a first electrode and a second electrode and defining a first and a second side and a first and a second edge;
a second solar cell having a first electrode and a second electrode and defining a first and a second side and a first and a second edge wherein a portion of the second side of the second solar cell adjacent the first edge is positioned at an interface adjacent a portion of the first side of the first solar cell adjacent the second edge of the first solar cell;
a first plurality of grid wires that are disposed on the first surface of the first solar cell and electrically connected to the first electrode of the first solar cell so as to collect charge carriers generated from the absorption of light by the first solar cell wherein the first plurality of grid wires are electrically connected to the second electrode of the second solar cell so as to electrically connect the first and second solar cells.

2. The assembly of claim 1, wherein the grid wires on the first solar cell extend outward of the second edge of the first solar cell to physically contact the second side of the second solar cell.

3. The assembly of claim 1, wherein the grid wires on the first solar cell are positioned so as to be retained inward of the second edge of the first solar cell and wherein the second solar cell is positioned on the first side of the first solar cell so that the grid wires contact the second side of the second solar cell at the interface between the first side of the first solar cell and the second side of the second solar cell.

4. The assembly of claim 1, wherein the first and second solar cells comprise CIGS based solar cells.

5. The assembly of claim 1, wherein the first surface of the first and second solar cells comprise a cathode and the second surface of the first and second solar cells comprise an anode.

6. The assembly of claim 5, further comprising a third solar cell having a first and a second side and defining a first and a second edge, wherein a portion of the second side of the third solar cell adjacent the first edge is positioned on the first side of the second electrode adjacent the second edge and the assembly further comprises a second plurality of grid wires that are disposed on the first surface of the second solar cell so as to collect charge carriers generated from the absorption of light by the second solar cell wherein the second plurality of grid wires are electrically connected to the second electrode of the third solar cell so that the first, second and third solar cells are electrically connected together.

7. The assembly of claim 1, further comprising a dielectric interposed between the first and second solar cells at the interface to inhibit short circuits between the first and second solar cells.

8. The assembly of claim 7, wherein the dielectric is interposed between the first electrode of the solar cell and the plurality of grid wires.

9. The assembly of claim 1, wherein the grid wires are bonded to the first electrode of the first solar cell.

10. The assembly of claim 9, wherein a first moisture barrier layer covers the grid wires and exposed portions of the first surface of the first solar cell.

11. The assembly of claim 8, wherein a second moisture barrier layer is disposed on the first moisture barrier layer, thereby forming a laminate on the coating the wires and the first surface.

12. The assembly of claim 11, wherein the first moisture barrier is a cured adhesive layer and the second moisture barrier layer is a polymer layer, wherein both layers are light transmitting so as to permit light to pass through and enter the first solar cell.

13. The assembly of claim 12, wherein the cured adhesive layer includes inorganic oxides that inhibits moisture penetration of the first solar cell.

14. The assembly of claim 12, wherein the second moisture barrier comprises a material selected from the group of fluorinated ethylene propylene (FEP), ethylene tetraflouroethylene (ETFE), polyethylene teraphthalate (PET) or thermoplastic olefin.

15. The assembly of claim 10, wherein a plurality of through holes are formed in the first moisture barrier so as to extend through the first moisture barrier between the first and second surfaces and wherein the plurality of through holes are filled with a conductive adhesive that contacts both the grid wires of the first solar cell and the second surface of the second solar cell so as to electrically interconnect the first and second solar cells.

16. A method of interconnecting a plurality of solar cells each having a first and second surface and a first and second edge, the method comprising:
(i) positioning grid wires on a first surface of the plurality of solar cells so that the grid wires collect charge carriers produced by the solar cells in response to the solar cells absorbing photons;
(ii) positioning a portion of the second surface of one solar cell adjacent the first edge of one solar cell adjacent the first surface of another solar cell adjacent the second edge of the other solar cell at an interface so that the plurality of grid wires of the other solar cell electrically contact the one solar cell;
(iii) repeating the positioning of act (ii) until a shingled array of electrically connected solar cells is formed.

17. The method of claim 16, wherein positioning grid wires on the first surface of the solar cell comprises positioning a laminate having a top layer and a bottom bonding layer that encapsulates the grid wires on the first surface of the solar cells and curing the bottom bonding layer on the first surface by applying heat and pressure to the laminate so that the plurality of grid wires electrically contact the first surface.

18. The method of claim 16, wherein positioning the grid wires on the first surface comprises positioning a laminate having a top layer and a bottom bonding layer that includes solid oxide particles that inhibit moisture intrusion into the solar cells.

19. The method of claim 16, wherein positioning a laminate on the first surface of the solar cells comprises positioning a laminate having a plurality of openings that extend from a first to a second surface of the carrier onto the first surface of the plurality of solar cells.

20. The method of claim 19, wherein the carrier is clear and light enters the solar cell through the laminate.

21. The method of claim 19, further comprising removing the carrier after the adhesive has secured the grid wires to the first surface of the solar cells.

22. The method of claim 19, further comprising positioning a conductive adhesive into the plurality of openings so that the conductive adhesive electrically couples to the plurality of grid wires on the first surface and so that the conductive adhesive electrically connects to the second surface of the adjacent solar cell at the interface so as to electrically connect the grid wires of one solar cell to the second solar cell.

23. The method of claim 16, wherein positioning the grid wires on the first surface comprises positioning the grid wires on the first surface so that a portion of the grid wires contacts the second surface of the adjacent solar cell.

24. The method of claim 16, further comprising positioning a dielectric at the interface between adjacent solar cells so as to provide increased short circuit protection between the adjacent solar cells.

25. The method of claim 16, wherein the step of curing the bottom bonding layer forms a moisture barrier attached to both the carrier layer and the first surface.
